(19) United States
(12) Patent Application Publication
(10) Pub. No.: US 2025/0083283 A1
(43) Pub. Date: Mar. 13, 2025

(54) METHOD FOR REMOVING LAMINATED MATERIAL ON SURFACE OF INTERMEDIATELY DISCHARGED SILICON WAFER

(71) Applicants: NANOLUB CO.,LTD, Nagoya-shi, Aichi (JP); KEITECH CO.,LTD, Nishikasugai-gun, Aichi (JP)

(72) Inventor: Yongsheng SUN, Nagoya-shi, Aichi (JP)

(21) Appl. No.: 18/705,010

(22) PCT Filed: Oct. 27, 2022
(86) PCT No.: PCT/JP2022/040233

§ 371 Date: Apr. 26, 2024

(30) Foreign Application Priority Data
Oct. 28, 2021 (JP) 2021-176923
Oct. 20, 2022 (JP) 2022-168275

(51) Int. Cl. B24C 11/00; B24C 1/04

(52) U.S. Cl. CPC B24C 11/00; B24C 1/04

(57) ABSTRACT

Provided is a method for removing a laminated material on a surface of a silicon wafer capable of considerably efficiently removing a laminated material on a surface of a silicon wafer at a low cost with a simple apparatus without a negative effect on environment or a serious damage on the silicon wafer as a substrate. A blasting process was performed by spraying boron carbide (B₄C) having a particle size of #220 as an abrasive on a laminate surface of a laminated material of an intermediately discharged silicon wafer using a blasting machine (dry type that sprays a dry abrasive, and a gravity type that sprays the abrasive fallen from a tank of the abrasive due to gravity on a compressed air) under spray conditions of a spray distance=120 mm and a spray pressure=0.2 MPa for five seconds.

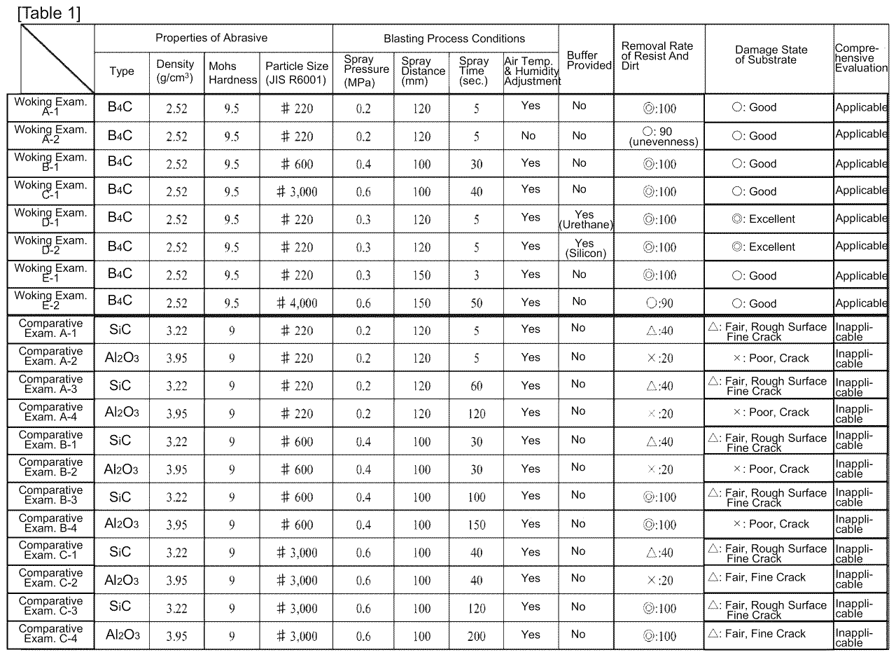

### TECHNICAL FIELD

The present invention relates to a method for removing a laminated material on a surface of an intermediately discharged silicon wafer used for reuse of the intermediately discharged silicon wafer discharged in a manufacturing process of a semiconductor integrated circuit.

### BACKGROUND ART

In manufacturing a semiconductor integrated circuit (semiconductor chip), mainly, a large number of circuit patterns including fine wiring, elements, and the like are formed by repeatedly performing processes, such as masking with a resist, exposure, and etching, on a surface of a device formed of a single crystal silicon wafer in a state where the circuit patterns are regularly arranged horizontally and vertically in a grid pattern, and subsequently (that is, after the circuit patterns are laminated on the device surface), the silicon wafer is cut out (diced) for each of the circuit patterns, thus forming rectangular semiconductor integrated circuits.

In the manufacture of the semiconductor integrated circuit described above, it is necessary to repeatedly perform various processes on the surface of the silicon wafer as a device with high accuracy. Therefore, a test and an evaluation for checking a finished condition are performed in each step of the processes, and the silicon wafers used for the test and the evaluation are discharged outside the manufacturing system without being provided for manufacturing a final product. Further, a silicon wafer (defective product) failed to be processed is also discharged outside the manufacturing system. Since the silicon wafers discharged outside the system during the manufacture (in the present invention, referred to as intermediately discharged silicon wafers) occupy a relatively high proportion (about 20%) in all the silicon wafers to be input, it is widely performed to reclaim the intermediately discharged silicon wafers to use them as a new raw material (therefore, the intermediately discharged silicon wafer is also referred to as a silicon wafer to be reclaimed).

For reclaiming the intermediately discharged silicon wafer, it is necessary to remove laminated materials on the surface of the silicon wafer. However, the laminated materials include materials having various hardnesses, such as SiO₂, SiC, Si₃N₄, GaAs, InP, Al, W, Ti, TIN, ITO, and Al₂O₃, and the surface of the silicon wafer is not uniformly polished by directly performing polishing. Therefore, as disclosed in Patent Document 1, a method in which a part of the laminated materials is removed by etching using alkaline and acidic agents and then perform polishing is employed. Further, as disclosed in Patent Document 2, there has been developed a method of removing the laminated materials on the surface of the silicon wafer by spraying a mixture fluid of compressed air and alumina or silicon carbide as an abrasive using a sand blasting machine.
Patent Document 1: Japanese Patent No. 3046807
Patent Document 2: Japanese Unexamined Patent Application Publication No. 2001-237201

### DISCLOSURE OF THE INVENTION

### Problems to be Solved by the Invention

However, in the method in which polishing is performed after removing the laminated materials on the surface of the silicon wafer by the etching using the agents as disclosed in Patent Document 1, the agents used for the etching possibly cause a problem on environment, and further, since it takes a long time to remove the laminated materials by the etching, the efficiency is poor, and performing at a low cost is difficult. Additionally, there is a defect that the agent erodes not only the laminated material but also the silicon wafer as a substrate.

It is an object of the present invention to provide a method for removing a laminated material on a surface of a silicon wafer capable of solving problems in the conventional methods for removing a laminated material on a surface of a silicon wafer as disclosed in Patent Documents 1 and 2, and capable of considerably efficiently removing the laminated material at a low cost with a simple apparatus without a negative effect on environment or a serious damage on the silicon wafer as a substrate.

### Solutions to the Problems

In the present invention, the invention described in claim 1 is a method for removing a laminated material (resist, metal, foreign matter, dirt, and the like) from a surface of an intermediately discharged silicon wafer discharged outside a system during manufacturing a semiconductor integrated circuit. The method includes spraying an abrasive having a density of 2.0 g/cm³ or more and less than 3.0 g/cm³ and a Mohs hardness of 9 or more and less than 11 to the surface of the intermediately discharged silicon wafer to forcibly peel off the laminated material on the surface of the intermediately discharged silicon wafer. The intermediately discharged silicon wafer in the present invention includes all the silicon wafers, for example, a dummy wafer and a test wafer, used for confirmation of manufacturing conditions, performance evaluation, inspections, and the like and discharged outside the system during the manufacture.

In the invention described in claim 2, which is in the invention described in claim 1, the abrasive has a particle size of from #150 (particle size measured by an electrical resistance test method according to Japanese Industrial Standard R6001, equivalent to average particle diameter=about 70 μm) to #10,000 (particle size measured by the electrical resistance test method according to JIS R6001, equivalent to average particle diameter=about 0.4 μm).

In the invention described in claim 3, which is in the invention described in claim 1 or 2, a spray pressure of the abrasive is from 0.15 MPa to 0.8 MPa.

In the invention described in claim 4, which is in the invention described in any of claims 1 to 3, the abrasive is boron carbide (B₄C).

In the invention described in claim 5, which is in the invention described in any of claims 1 to 4, the method includes spraying the abrasive to the surface of the intermediately discharged silicon wafer placed on a base. A buffer is interposed between the base and the intermediately discharged silicon wafer.

### Effects of the Invention

According to the method for removing a laminated material on a surface of an intermediately discharged silicon wafer of the present invention, a laminated material on a surface of a silicon wafer can be considerably efficiently removed at a low cost with a simple apparatus without a negative effect on environment or a serious damage on the silicon wafer as a substrate.

### Description of Preferred Embodiments

In a method for removing a laminated material on a surface of an intermediately discharged silicon wafer according to the present invention, an abrasive having a specific property is sprayed to the surface of the intermediately discharged silicon wafer at a predetermined spray pressure using a blasting machine, thereby forcibly peeling off the laminated material (resist, metal, foreign matter, dirt, and the like) on the surface of the intermediately discharged silicon wafer.

### Blasting Machine

In the method for removing the laminated material on the surface of the intermediately discharged silicon wafer according to the present invention, as an apparatus for spraying a predetermined abrasive to the surface of the intermediately discharged silicon wafer, an ordinary blasting machine can be appropriately used. That is, a blasting machine including conveying means that conveys the intermediately discharged silicon wafer, blast processing means that sprays an abrasive (or a slurry containing the abrasive) as a blasting material toward the intermediately discharged silicon wafer, recovering means that recovers the abrasive and the like after the spraying, control means that integrally controls the respective means, and the like can be appropriately used. Further, as the blasting machine, one of a dry blasting method (air blasting machine) that sprays a dry abrasive (fine powder) can be appropriately used. That is, the use of the air blasting machine is preferable because a processing surface can be cooled only by spraying air after removing the laminated material, and a situation in which an abrasive mixed with water sticks to a member of the apparatus like a case where a wet type blasting machine is used can be avoided. Additionally, when the abrasive is sprayed to the surface of the intermediately discharged silicon wafer using the air blasting machine, it is preferable to swing (reciprocate) a spray nozzle in a plane parallel to the surface of the intermediately discharged silicon wafer (swing the spray nozzle in a direction perpendicular to a longitudinal direction of the conveying means, such as a belt conveyor, of the intermediately discharged silicon wafer.

In addition, as the air blasting machine, a direct-pressure blasting machine that sprays an abrasive conveyed by a compressed air supplied in a tank in which the abrasive has been put on an airflow of an additionally supplied compressed air using a blast gun, a gravity blasting machine that sprays an abrasive fallen from a tank of the abrasive due to gravity on a compressed air, or the like can be appropriately used. The use of the gravity blasting machine is preferable because a spray velocity and a spray pressure of the abrasive can be easily controlled. When the abrasive is fine particles of #5,000 or more, the use of the direct-pressure blasting machine is preferable because the spray velocity and the spray pressure of the abrasive can be easily controlled.

While the spray pressure of the abrasive of the blasting machine is not specifically limited, a range of from 0.15 MPa to 0.8 MPa (0.15 MPa or more and less than 0.8 MPa) is preferable because a satisfactory removal efficiency of the laminated material from the surface of the intermediately discharged silicon wafer is provided, and a damage of a superficial layer of the intermediately discharged silicon wafer can be suppressed to be low. The spray pressure is preferably from 0.2 MPa to 0.6 MPa, and more preferably from 0.3 MPa to 0.5 MPa.

Meanwhile, a distance between the spray nozzle and the silicon wafer surface (hereinafter referred to as a spray distance) when the abrasive is sprayed to the surface of the intermediately discharged silicon wafer by the blasting machine is not specifically limited. However, a range of from 80 mm to 200 mm is preferable because a satisfactory removal efficiency of the laminated material from the surface of the intermediately discharged silicon wafer is provided, and a damage of a superficial layer of the intermediately discharged silicon wafer can be suppressed to be low. The spray distance is more preferably from 100 mm to 150 mm.

Meanwhile, a spray time when the abrasive is sprayed to the surface of the intermediately discharged silicon wafer by the blasting machine is not specifically limited. However, a range of from 10 seconds to 50 seconds is preferable because a satisfactory removal efficiency of the laminated material from the surface of the intermediately discharged silicon wafer is provided, and a damage of a superficial layer of the intermediately discharged silicon wafer can be suppressed to be low. The spray time is more preferably from 20 seconds to 40 seconds. In addition, a coverage (visually observed processing area (collision rate of abrasive)) when the abrasive is sprayed to the surface of the intermediately discharged silicon wafer is preferably adjusted to from 100% to 300%.

The spray pressure and the spray distance of the abrasive described above need to be adjusted according to a count of the abrasive. That is, when an abrasive of a large count (that is, an abrasive having a small particle diameter, approximately #1,000 or more) is sprayed, it is necessary to increase the spray pressure (approximately 0.5 MPa or more) and decrease the spray distance (approximately less than 150 mm). Meanwhile, when an abrasive of a small count (that is, an abrasive having a large particle diameter) is sprayed, it is necessary to decrease the spray pressure and increase the spray distance.

When the abrasive (especially, boron carbide) is sprayed to the surface of the intermediately discharged silicon wafer using the air blasting machine, a temperature of the compressed air (or another gas) to be sprayed is preferably set to 15° C. or less. In the intermediately discharged silicon wafer (that is, a single crystal silicon wafer), the crystalline structure changes at 594 K (that is, 319° C.), and characteristics possibly change. However, by controlling the temperature of the compressed air (or another gas) to 15° C. or less as described above, the surface of the intermediately discharged silicon wafer can be considerably uniformly polished while suppressing the temperature rise of the surface of the intermediately discharged silicon wafer when the abrasive collides to avoid the change of the crystalline structure of the intermediately discharged silicon wafer. The temperature of the compressed air (or another gas) to be sprayed is more preferably 10° C. or less.

In addition, when the abrasive (especially, boron carbide) is sprayed to the surface of the intermediately discharged silicon wafer using the air blasting machine, it is preferable to control a moisture percentage (that is, humidity=water vapor amount/saturated water vapor amount×100) to be low to avoid saturation (that is, to avoid condensation) of water vapor in the compressed air (or another gas) to be sprayed. The high moisture percentage in the compressed air (that is, water content of the compressed air exceeding the amount of saturated water vapor at the temperature of the compressed air) is not preferable because the adjustment of the spray pressure of the abrasive becomes difficult, and the abrasive easily attaches to the surface of the intermediately discharged silicon wafer. On the other hand, the moisture percentage in the compressed air excessively decreased to less than 30% is not preferable because a static electricity is easily generated when the abrasive is sprayed to the surface of the intermediately discharged silicon wafer. Further, as described above, as a method of controlling the temperature and the moisture percentage of the compressed air (or another gas) to be sprayed to be low, when a cooling method, that is, a method in which dehumidification is performed by cooling air to condense the water content in the air similarly to dehumidification by an air conditioner is employed, an air having a dew point under pressure of about 10° C. is obtained. Therefore, it is preferable because the temperature and the moisture percentage of the compressed air can be efficiently controlled compared with an adsorption method and a membrane method.

Furthermore, when the abrasive is sprayed to the surface of the intermediately discharged silicon wafer using a surface air blasting machine for the intermediately discharged silicon wafer, it is preferable to swing (reciprocate) the spray nozzle above the surface of the intermediately discharged silicon wafer. When the spray nozzle is swung, it is preferable to set a swing width to be larger than a width (usually, 6 inches (15.24 cm) to 12 inches (30.48 cm)) of the intermediately discharged silicon wafer to avoid unevenness in spray time per unit time to the surface of the intermediately discharged silicon wafer. Meanwhile, the excessively large swing width compared with the width of the intermediately discharged silicon wafer causes a loss in the polishing time. Therefore, it is preferable to adjust a difference between the swing width and the width of the intermediately discharged silicon wafer to 50 mm or more and 100 mm or less (25 mm or more and 50 mm or less in each of left and right). As described above, when the spray nozzle is swung, it is preferable to swing the spray nozzle such that a distal end of the spray nozzle moves in a plane parallel to the surface of the intermediately discharged silicon wafer.

### Abrasive (Blasting Material)

Meanwhile, as the abrasive used in the method for removing the laminated material on the surface of the intermediately discharged silicon wafer according to the present invention, it is necessary to use one not only having a high hardness enough to remove the laminated material by spraying the abrasive to collide against the laminated material, but also being capable of accurately avoiding a situation in which the abrasive grinds the silicon wafer as a substrate when the laminated material is removed by spraying the abrasive to collided against the laminated material. When an abrasive containing a material having a relatively high density, such as silicon carbide (SiC, density=3.2 g/cm³) and aluminum oxide (Al₂O₃, density=4.3 g/cm³), which are conventional abrasives in the blasting process, is used, the spray pressure needs to be increased to obtain a spray velocity required for removing the laminated material on the surface of the silicon wafer. However, increasing the spray pressure to raise the spray velocity increases a collision energy when the abrasive collides against the surface of the silicon wafer due to the high density of the abrasive. Thus, not only the laminated material is removed, but also the silicon wafer is possibly damaged. Further, the collision of the abrasive causes heat generation of the silicon wafer, leading to a situation in which the silicon wafer becomes unusable. Therefore, in the method for removing the laminated material on the surface of the intermediately discharged silicon wafer according to the present invention, it is necessary to use the abrasive having the density of 2.0 g/cm³ or more and less than 3.0 g/cm³.

On the other hand, the hardnesses of silicon carbide (SiC), aluminum oxide (Al₂O₃), and the like as the conventional abrasives of the blast process are not sufficiently high compared with the hardness of the laminated material to be removed. Therefore, the use of silicon carbide, aluminum oxide, and the like as the abrasive makes efficiently removing the laminated material difficult, requires a long time for the removal, and fails to completely remove the laminated material and allows the laminated material to remain on the surface of the silicon wafer. When the spray velocity of the abrasive is increased to avoid such a situation, as described above, the increase of the collision energy causes a situation in which the surface of the silicon wafer as the substrate is ground. Therefore, in the method for removing the laminated material on the surface of the intermediately discharged silicon wafer according to the present invention, to effectively avoid the situation in which the silicon wafer is ground as described above, it is necessary to use the abrasive having a Mohs hardness of 9 or more and less than 11.

Accordingly, in the method for removing the laminated material on the surface of the intermediately discharged silicon wafer according to the present invention, to effectively avoid the situation in which the silicon wafer is ground while cleanly removing the laminated material without a residue, it is necessary to use the abrasive having the density of 2.0 g/cm³ or more and less than 3.0 g/cm³ and having the Mohs hardness of 9 or more and less than 11. Then, as such an abrasive, boron carbide (B₄C) having the density of 2.51 g/cm³ and having the Mohs hardness of 9.497 (micro hardness of about 5,000 kgf/mm²) can be appropriately used. While boron carbide is relatively expensive, the spray pressure can be set to be low in the blasting process, therefore, not only the laminated material can be removed in a short processing time (that is, with a small amount of the used abrasive), but also the damage (grinding) of the silicon wafer as the substrate can be effectively avoided.

In addition, while a particle size (size of particle) of the abrasive is not specifically limited, adjusting the particle size in a range of from #150 to #10,000 (average particle diameter of from about 0.4 μm to about 70 μm) is preferable because the laminated material can be efficiently removed, and the damage of the silicon wafer as the substrate can be effectively avoided. The particle size (size of particle) of the abrasive is more preferably from #400 to #7,000 (average particle diameter=1.6 μm to 30 μm), and especially preferably from #600 to #5,000 (average particle diameter=2.5 μm to 20 μm).

Furthermore, in the method for removing the laminated material on the surface of the intermediately discharged silicon wafer according to the present invention, when the blasting process is performed using the specific abrasive as described above, it is preferable to interpose a buffer between the silicon wafer as the substrate and a placement table (a base on which the intermediately discharged silicon wafer is placed during the blasting process) for purpose of reducing the collision energy of the abrasive caused by a force due to the collision of the abrasive such that the buffer is in contact with a backside surface (a surface on which the laminated material is not laminated) of the silicon wafer. As such a buffer, while an elastic sheet of a rubber, a silicon resin, or a foamed resin can be appropriately used, the use of one made of a urethane rubber is preferable because a static electricity is less likely to be generated when the abrasive collides against the surface of the silicon wafer, and the abrasive is less likely to attach to the surface of the silicon wafer. The buffer having the hardness of 20 to 90 measured by a method according to JIS K6253-3 (that is, hardness measured with a durometer (type A)) (elasticity modulus=5 MPa to 20 MPa) is preferable because a satisfactory removal efficiency of the laminated material from the surface of the intermediately discharged silicon wafer is provided, and a damage of a superficial layer of the intermediately discharged silicon wafer can be suppressed to be low. Meanwhile, while a thickness of the buffer is not specifically limited, to sufficiently absorbing and diffusing the impact at the collision of the abrasive, the thickness of the buffer is preferably 2.0 mm or more, and from the aspect of ease of an installation operation, the thickness of the buffer is preferably 7.0 mm or less. The thickness of the buffer is preferably 2.0 mm or more, and from the aspect of ease of an installation operation, the thickness of the buffer is preferably 20.0 mm or less. In addition, the thickness of the buffer is more preferably 8.0 mm or more and less than 12.0 mm.

In addition, a shock-absorbing material (buffer material) may be simple plate-shaped one (that is, the whole surface (100%) abuts on the backside surface of the intermediately discharged silicon wafer). However, the use of one provided with a large number of through-holes (those having diameters of about 3.0 mm or less) punched to be regularly and uniformly distributed, one provided with protrusions in a columnar shape, a prismatic shape, a hemispherical shape, a rectangular parallelepiped shape, a flat hollow columnar shape, a flat hollow prismatic shape, and the like having a predetermined height (about 3.0 mm or less) disposed to protrude to be regularly and uniformly distributed, or the like is preferable because a heat generated at the collision of the abrasive can be easily emitted outside, and the satisfactory cooling efficiency is provided. When the shock-absorbing material is provided with a large number of the through-holes or a large number of the protrusions as described above, adjusting an abutting proportion between the surface of the shock-absorbing material and the backside surface of the intermediately discharged silicon wafer to about 50% to 80% is preferable because both of an impact buffering efficiency at the collision of the abrasive and a cooling efficiency can be made satisfactory.

In the method for removing the laminated material on the surface of the intermediately discharged silicon wafer according to the present invention, the blasting process using the abrasive having the specific properties as described above is performed on the silicon wafer. However, the blasting process may be performed at room temperature, and the blasting process may be performed under an atmosphere at a temperature higher than room temperature, at which the laminated material to be removed softens (for example, under an atmosphere of from Tg (glass transition point) to about Tg+10° C. of the laminated material).

In addition, when the laminated material on the surface of the intermediately discharged silicon wafer is removed by the removing method according to the present invention, blasting process conditions are preferably adjusted such that a surface roughness (Ra) of the surface of the intermediately discharged silicon wafer becomes 0.5 μm or less, and the surface roughness (Ra) is more preferably adjusted to 0.4 μm or less.

### WORKING EXAMPLES

The following describes the method for removing the laminated material on the surface of the intermediately discharged silicon wafer according to the present invention with working examples in detail. However, the present invention is not limited to aspects of those working example, and can be changed as necessary without departing from the gist of the present invention. Evaluation methods of physical properties and characteristics in the working examples and comparative examples are as follows.

### Removal State of Laminated Material

The surface of the silicon wafer after removing the laminated material, such as a resist, was enlarged (1,000 times) by an electron microscope and visually observed, and thus the removal state of the laminated material, such as a resist, was sensory evaluated in four levels below. The evaluation was performed at different three points on the same silicon wafer, and an average level (Excellent, Good, Fair, Poor) of the respective evaluations was determined as a final evaluation.

Excellent: a removal rate of the laminated material is 100% (laminated material is completely removed).

Good: the removal rate of the laminated material is approximately 60% or more and less than 100%.

Fair: the removal rate of the laminated material is approximately 20% or more and less than 60%.

Poor: the removal rate of the laminated material is approximately less than 20%.

### Damage State of Substrate

The surface of the silicon wafer after removing the laminated material, such as a resist, was enlarged (1,000 times) by an electron microscope and visually observed, and thus the damage state (grinding state) of the surface of the silicon wafer as the substrate was sensory evaluated in four levels below. The evaluation was performed at different three points on the same silicon wafer, and an average level (Excellent, Good, Fair, Poor) of the respective evaluations was determined as a final evaluation.

Excellent: the surface of the substrate is not damaged at all.

Good: the surface of the substrate is almost undamaged (a small damage is slightly recognized).

Fair: the surface of the substrate is rough, or a fine crack is recognized on the surface of the substrate.

Poor: a crack is clearly recognized on the surface of the substrate.

### Working Example A-1

Boron carbide (B₄C) having the particle size of #220 (average particle diameter=51 μm) in a grid type as the abrasive was sprayed on a laminate surface of the laminated material of the intermediately discharged silicon wafer (silicon wafer to be reclaimed) from a nozzle having a diameter of 9.0 mmφ using a blasting machine for five seconds under spray conditions of the spray pressure of 0.2 MPa and the spray distance=120 mm, thus performing the blasting process. The used blasting machine was the dry type that sprays a dry abrasive, and a gravity type (air blasting machine) that sprays an abrasive fallen from a tank of the abrasive due to gravity on a compressed air. The used blasting machine conveys the intermediately discharged silicon wafer as a process target at a constant speed by a conveyor as the conveying means. As the intermediately discharged silicon wafer, an oxide film was evaporated on a surface of a silicon wafer having a diameter of 200 mm, a resist (photoresist) was applied over the oxide film to mask it, which was subsequently exposed and etched to form a base (thickness of about 0.3 μm) of a circuit pattern, and cut in a rectangular shape of 80 mm×50 mm to be used.

When the blasting process was performed as described above, by passing through an air drier, the temperature of the compressed air was adjusted to 13±2° C. and the moisture percentage of the compressed air was adjusted to 40±5%. A surface roughness (Ra) of the intermediately discharged silicon wafer after removing the laminated material by the blasting process was 0.48 μm. Then, the intermediately discharged silicon wafer was washed with pure water and dried at room temperature, subsequently, the removal state of the laminated material and the damage state of the substrate were evaluated by the above-described methods. Table 1 indicates the evaluation result together with the properties of the abrasive and the blasting process conditions.

### Working Example A-2

When the abrasive was sprayed to the intermediately discharged silicon wafer using the blasting machine, the temperature and the moisture percentage of the compressed air were not adjusted (the temperature and the moisture percentage of the compressed air were 23° C. and 55%, respectively). Then, similarly to the working example A-1 excluding that, the blasting process was performed on the intermediately discharged silicon wafer, which was washed with pure water and dried at room temperature. Then, the removal state of the laminated material and the damage state of the substrate were evaluated by the methods similar to those of the working example A-1. Table 1 indicates the evaluation result together with the properties of the abrasive and the blasting process conditions.

### Comparative Example A-1

The blasting process was performed on the intermediately discharged silicon wafer, which was washed with pure water and dried at room temperature similarly to the working example A-1 excluding that the abrasive to be used was changed to silicon carbide (SiC) having the particle size of #220. Then, the removal state of the laminated material and the damage state of the substrate were evaluated by the methods similar to those of the working example A-1. Table 1 indicates the evaluation result together with the properties of the abrasive and the blasting process conditions.

### Comparative Example A-2

The blasting process was performed on the intermediately discharged silicon wafer, which was washed with pure water and dried at room temperature similarly to the working example A-1 excluding that the abrasive to be used was changed to aluminum oxide (Al₂O₃) having the particle size of #220. Then, the removal state of the laminated material and the damage state of the substrate were evaluated by the methods similar to those of the working example A-1. Table 1 indicates the evaluation result together with the properties of the abrasive and the blasting process conditions.

### Comparative Example A-3

The blasting process was performed on the intermediately discharged silicon wafer, which was washed with pure water and dried at room temperature similarly to the working example A-1 excluding that the abrasive sprayed to a backside surface of the intermediately discharged silicon wafer was changed to silicon carbide (SiC) having the particle size of #220, and the spray time was changed to 60 seconds. Then, the removal state of the laminated material and the damage state of the substrate were evaluated by the methods similar to those of the working example A-1. Table 1 indicates the evaluation result together with the properties of the abrasive and the blasting process conditions.

### Comparative Example A-4

The blasting process was performed on the intermediately discharged silicon wafer, which was washed with pure water and dried at room temperature similarly to the working example A-1 excluding that the abrasive sprayed to the backside surface of the intermediately discharged silicon wafer was changed to aluminum oxide (Al₂O₃) having the particle size of #220, and the spray time was changed to 120 seconds. Then, the removal state of the laminated material and the damage state of the substrate were evaluated by the methods similar to those of the working example A-1. Table 1 indicates the evaluation result together with the properties of the abrasive and the blasting process conditions.

### Working Example B-1

The blasting process was performed on the intermediately discharged silicon wafer, which was washed with pure water and dried at room temperature similarly to the working example A-1 excluding that the abrasive sprayed to the backside surface of the intermediately discharged silicon wafer was changed to boron carbide (B₄C) having the particle size of #600 (average particle diameter=20 μm), the spray distance was changed to 100 mm, the spray pressure was changed to 0.4 MPa, and the spray time was changed to 30 seconds. Then, the removal state of the laminated material and the damage state of the substrate were evaluated by the methods similar to those of the working example A-1. Table 1 indicates the evaluation result together with the properties of the abrasive and the blasting process conditions.

### Comparative Example B-1

The blasting process was performed on the intermediately discharged silicon wafer, which was washed with pure water and dried at room temperature similarly to the working example B-1 excluding that the abrasive to be used was changed to silicon carbide (SiC) having the particle size of #600. Then, the removal state of the laminated material and the damage state of the substrate were evaluated by the methods similar to those of the working example A-1. Table 1 indicates the evaluation result together with the properties of the abrasive and the blasting process conditions.

### Comparative Example B-2

The blasting process was performed on the intermediately discharged silicon wafer, which was washed with pure water and dried at room temperature similarly to the working example B-1 excluding that the abrasive to be used was changed to aluminum oxide (Al₂O₃) having the particle size of #600. Then, the removal state of the laminated material and the damage state of the substrate were evaluated by the methods similar to those of the working example A-1. Table 1 indicates the evaluation result together with the properties of the abrasive and the blasting process conditions.

### Comparative Example B-3

The blasting process was performed on the intermediately discharged silicon wafer, which was washed with pure water and dried at room temperature similarly to the working example B-1 excluding that the abrasive sprayed to the backside surface of the intermediately discharged silicon wafer was changed to silicon carbide (SiC) having the particle size of #600, and the spray time was changed to 100 seconds. Then, the removal state of the laminated material and the damage state of the substrate were evaluated by the methods similar to those of the working example A-1. Table 1 indicates the evaluation result together with the properties of the abrasive and the blasting process conditions.

### Comparative Example B-4

The blasting process was performed on the intermediately discharged silicon wafer, which was washed with pure water and dried at room temperature similarly to the working example B-1 excluding that the abrasive sprayed to the backside surface of the intermediately discharged silicon wafer was changed to aluminum oxide (Al₂O₃) having the particle size of #600, and the spray time was changed to 150 seconds. Then, the removal state of the laminated material and the damage state of the substrate were evaluated by the methods similar to those of the working example A-1. Table 1 indicates the evaluation result together with the properties of the abrasive and the blasting process conditions.

### Working Example C-1

The blasting process was performed on the intermediately discharged silicon wafer, which was washed with pure water and dried at room temperature similarly to the working example A-1 excluding that the abrasive sprayed to the backside surface of the intermediately discharged silicon wafer was changed to boron carbide (B₄C) having the particle size of #3,000 (average particle diameter=5 μm), the spray distance was changed to 100 mm, the spray pressure was changed to 0.6 MPa, and the spray time was changed to 40 seconds. Then, the removal state of the laminated material and the damage state of the substrate were evaluated by the methods similar to those of the working example A-1. Table 1 indicates the evaluation result together with the properties of the abrasive and the blasting process conditions.

### Comparative Example C-1

The blasting process was performed on the intermediately discharged silicon wafer, which was washed with pure water and dried at room temperature similarly to the working example C-1 excluding that the abrasive to be used was changed to silicon carbide (SiC) having the particle size of #3,000. Then, the removal state of the laminated material and the damage state of the substrate were evaluated by the methods similar to those of the working example A-1. Table 1 indicates the evaluation result together with the properties of the abrasive and the blasting process conditions.

### Comparative Example C-2

The blasting process was performed on the intermediately discharged silicon wafer, which was washed with pure water and dried at room temperature similarly to the working example C-1 excluding that the abrasive to be used was changed to aluminum oxide (Al₂O₃) having the particle size of #3,000. Then, the removal state of the laminated material and the damage state of the substrate were evaluated by the methods similar to those of the working example A-1. Table 1 indicates the evaluation result together with the properties of the abrasive and the blasting process conditions.

### Comparative Example C-3

The blasting process was performed on the intermediately discharged silicon wafer, which was washed with pure water and dried at room temperature similarly to the working example C-1 excluding that the abrasive sprayed to the backside surface of the intermediately discharged silicon wafer was changed to silicon carbide (SiC) having the particle size of #3,000, and the spray time was changed to 120 seconds. Then, the removal state of the laminated material and the damage state of the substrate were evaluated by the methods similar to those of the working example A-1. Table 1 indicates the evaluation result together with the properties of the abrasive and the blasting process conditions.

### Comparative Example C-4

The blasting process was performed on the intermediately discharged silicon wafer, which was washed with pure water and dried at room temperature similarly to the working example C-1 excluding that the abrasive sprayed to the backside surface of the intermediately discharged silicon wafer was changed to aluminum oxide (Al₂O₃) having the particle size of #3,000, and the spray time was changed to 200 seconds. Then, the removal state of the laminated material and the damage state of the substrate were evaluated by the methods similar to those of the working example A-1. Table 1 indicates the evaluation result together with the properties of the abrasive and the blasting process conditions.

### Working Example D-1

When the abrasive was sprayed to the backside surface of the intermediately discharged silicon wafer by the method similar to that of the working example A-1, an urethane rubber sheet was interposed as a buffer between the backside surface (surface on which the laminated material is not laminated) of the intermediately discharged silicon wafer and a placement table (metal) of the blasting machine, the spray pressure was changed to 0.3 MPa, and the spray time was changed to 5 seconds. The used urethane rubber sheet had a hardness of 55 measured by the method according to JIS K6253-3 and a thickness of about 10.0 mm. Then, similarly to the working example A-1 other than that, the blasting process was performed on the silicon wafer, which was washed with pure water and dried at room temperature. Then, the removal state of the laminated material and the damage state of the substrate were evaluated by the methods similar to those of the working example A-1. Table 1 indicates the evaluation result together with the properties of the abrasive and the blasting process conditions.

### Working Example D-2

The blasting process was performed on the silicon wafer, which was washed with pure water and dried at room temperature similarly to the working example D-1 excluding that the buffer interposed between the backside surface (surface on which the laminated material is not laminated) of the intermediately discharged silicon wafer and the placement table (metal) of the blasting machine when the abrasive was sprayed to the backside surface of the intermediately discharged silicon wafer was changed to a silicon rubber sheet having a hardness of 30 measured by the method according to JIS K6253-3 and a thickness of about 10.0 mm. Then, the removal state of the laminated material and the damage state of the substrate were evaluated by the methods similar to those of the working example A-1. Table 1 indicates the evaluation result together with the properties of the abrasive and the blasting process conditions.

### Working Example E-1

The blasting process was performed on the intermediately discharged silicon wafer, which was washed with pure water and dried at room temperature similarly to the working example A-1 excluding that the abrasive sprayed to the backside surface of the intermediately discharged silicon wafer was changed to boron carbide (B₄C) having the particle size of #220 (average particle diameter=62 μm), the spray distance was changed to 150 mm, the spray pressure was changed to 0.3 MPa, and the spray time was changed to 3 seconds. Then, the removal state of the laminated material and the damage state of the substrate were evaluated by the methods similar to those of the working example A-1. Table 1 indicates the evaluation result together with the properties of the abrasive and the blasting process conditions.

### Working Example E-2

The blasting process was performed on the intermediately discharged silicon wafer, which was washed with pure water and dried at room temperature similarly to the working example A-1 excluding that the abrasive sprayed to the backside surface of the intermediately discharged silicon wafer was changed to boron carbide (B₄C) having the particle size of #4,000 (average particle diameter=3 μm), the spray distance was changed to 150 mm, the spray pressure was changed to 0.6 MPa, and the spray time was changed to 50 seconds. Then, the removal state of the laminated material and the damage state of the substrate were evaluated by the methods similar to those of the working example A-1. Table 1 indicates the evaluation result together with the properties of the abrasive and the blasting process conditions.
[Table 1]

It is seen from Table 1 that when the blasting process was performed on the intermediately discharged silicon wafer by the methods of the working examples A-1, B-1, C-1, D-1, D-2, E-1, E-2 meeting the requirements of the present invention (invention according to claim 1), both of the removal state of the laminated material and the damage state of the substrate were satisfactory. Further, it is seen that when the buffer was interposed between the backside surface of the intermediately discharged silicon wafer and the placement table of the blasting machine like the working examples E-1, E-2, the damage state of the substrate was excellent. In contrast, it is seen that when the blasting process was performed on the intermediately discharged silicon wafer by the methods of the comparative examples A-1 to A-4, B-1 to B-4, C-1 to C-4 not meeting the requirements of the present invention, the removal state of the laminated material was poor, or the damage state of the substrate was poor.

### INDUSTRIAL APPLICABILITY

The method for removing the laminated material on the intermediately discharged silicon wafer according to the present invention provides the excellent effect as described above. Therefore, it can be appropriately used as a method for removing a laminated material from a surface of an intermediately discharged silicon wafer for reclaiming the intermediately discharged silicon wafer.

1. A method for removing a laminated material from a surface of an intermediately discharged silicon wafer discharged outside a system during manufacturing a semiconductor integrated circuit, the method comprising
spraying an abrasive having a density of 2.0 g/cm³ or more and less than 3.0 g/cm³ and a Mohs hardness of 9 or more and less than 11 to the surface of the intermediately discharged silicon wafer to forcibly peel off the laminated material on the surface of the intermediately discharged silicon wafer.

2. The method for removing a laminated material on a surface of an intermediately discharged silicon wafer according to claim 1, wherein
the abrasive has a particle size of from #150 to #10,000.

3. The method for removing a laminated material on a surface of an intermediately discharged silicon wafer according to claim 1, wherein
a spray pressure of the abrasive is from 0.15 MPa to 0.8 MPa.

4. The method for removing a laminated material on a surface of an intermediately discharged silicon wafer according to according to claim 1, wherein
the abrasive is boron carbide (B₄C).

5. The method for removing a laminated material on a surface of an intermediately discharged silicon wafer according to according to claim 1, the method comprising
spraying the abrasive to the surface of the intermediately discharged silicon wafer placed on a base, wherein
a buffer is interposed between the base and the intermediately discharged silicon wafer.
